(19) United States
(12) Patent Application Publication
(10) Pub. No.: US 2008/0111237 A1
(43) Pub. Date: May 15, 2008

(54) SEMICONDUCTOR DEVICE MANUFACTURED USING AN ELECTROCHEMICAL DEPOSITION PROCESS FOR COPPER INTERCONNECTS

(75) Inventors: Montray Cantrell Leavy, McKinney, TX (US); Jeffrey Alan West, Dallas, TX (US); Kyle James McPherson, Allen, TX (US); Richard Allen Faust, Dallas, TX (US); Lixin Wu, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/559,495

(22) Filed: Nov. 14, 2006

(51) Int. Cl. H01L 23/52; H01L 21/4763

(52) U.S. Cl. 257/741; 438/618; 257/E21.575; 257/E23.141

(57) ABSTRACT

A method of manufacturing a semiconductor device that comprises forming an insulating layer over a semiconductive substrate 110 and forming a copper interconnect. Forming the interconnect includes etching an interconnect opening in the insulating layer and filling the opening with copper plating. Filling with copper plating includes using a first and second ECD. An electrolyte solution of the first and second ECD contains organic additives, and a current of the first ECD is greater than a current of the second ECD.

### TECHNICAL FIELD

The invention is directed to the manufacture of semiconductor devices, such as integrated circuits (ICs), and in particular, methods of forming copper interconnections and ICs that comprise such interconnects.

### BACKGROUND

The use of copper-containing interconnections in semiconductor devices is increasingly popular because of copper's low electrical resistance and superior resistance to electromigration, as compared to aluminum containing interconnects. The process of forming copper interconnections in not without problems, however. Copper is not amenable to conventional etching and patterning processes, such as those used for aluminum. Consequently, copper interconnects are formed using single or dual damascence processes, where an opening in an insulating layer is filled with copper.

The process of filling the single or dual damascence opening with copper includes an electrochemical deposition (ECD) process. Typically, a semiconductor wafer is placed into a copper-containing electrolyte solution and a current is applied to plate copper into the opening. The formation of a high yield of copper interconnects having sufficiently low electrical resistance is highly dependent upon the applied current and the composition of the electrolyte solution used in the ECD process. For example, the current is carefully adjusted to control the rate of copper plating. The concentration of organic additives in the electrolyte solution is also carefully adjusted to control the grain structure and growth rate of deposited copper. Nevertheless, problems can still arise with the reliability of the semiconductor devices, as reflected by an increase in resistance of a number interconnects after a period of use.

Accordingly, what is needed in the art is a method of manufacturing semiconductor devices having high yields of low resistance copper interconnects that are also reliable.

### SUMMARY

The invention provides, in one embodiment, a method of manufacturing a semiconductor device. The method comprises forming an insulating layer over a semiconductive substrate and forming a copper interconnect. Forming the interconnect includes etching an interconnect opening in the insulating layer and filling the opening with copper plating. Filling with copper plating includes using a first ECD and a second ECD. An electrolyte solution of the first and second ECD contains organic additives, and a current of the first ECD is greater than a current of the second ECD.

Another embodiment is a method of manufacturing an IC. The method comprises forming electrical components in or on a substrate and depositing an insulating layer on the substrate. The method also comprises forming copper interconnects configured to couple the electrical components together. Forming the copper interconnects includes etching an interconnect opening in the insulating layer, depositing a barrier layer and a seed layer in the opening and filling the opening with copper as described above. The electrolyte solution of the first and second ECD contains organic additives comprising at least one of: suppressors, accelerators or levelers.

Still another embodiment is an IC. The IC comprises electrical components located in or on a substrate, an insulating layer located over the electrical components, and copper interconnects in the insulating layer. The copper interconnects are configured to interconnect the electrical components. There is a higher concentration of organic additive by-products in a central location than in a peripheral location of at least one of the interconnects.

### DRAWINGS

The invention is described with reference to example embodiments and to accompanying drawings, wherein:

FIGS. 1-9 show cross-sectional views at selected steps in an example method of manufacturing a semiconductor device of the invention;

FIG. 10 also illustrates a cross-sectional view of an IC of the invention; and

FIG. 11 presents a theoretical concentration profile of organic additive by-products in an interconnect manufactured by processes such as presented in FIGS. 1-9.

### DETAILED DESCRIPTION

The invention benefits from the discovery that the reliability of copper interconnects can be improved by increasing the concentration of organic additive by-products present in the copper interconnect by decreasing the current at a particular stage in an ECD process. The organic additive by-products help improve the grain structure of the plated copper and thereby facilitate the formation of interconnects that are more reliable than interconnects constructed in the presence of lower by-product concentrations. The ECD process comprises at least two-steps: a first step with a high first current to initiate copper plating, followed by a second step with a lower second current to promote by-product formation. Semiconductor devices produced using a fabrication scheme including these steps have a high yield of low-resistance and reliable interconnects.

The term high yield as used here refers to the percentage of interconnects that have an acceptable low resistance shortly after semiconductor device fabrication. Device fabrication schemes require that a large percentage of the interconnects have a low resistance. Typically the resistance of the interconnects is characterized by measuring the resistance of vias that are electrically coupled to the interconnects. The vials resistance at the moment of complete fabrication must be below a target value to pass a failure mode test. The term yielding interconnect as used herein refers to a completely fabricated interconnect with a via resistance measured to be below a specified target. E.g., in some embodiments, at least about 99.98 percent of the vias tested have a resistance that is about 10 ohms or less. The term reliable interconnect as used herein refers to interconnects whose resistance does not substantially change after a period of use or simulated aging. E.g., some embodiments of a device fabrication scheme require that after a thermal bake comprising 200° C. for 168 hours, the resistance of at least 99.98 percent of the interconnects have changed by less than about 20 percent. In other embodiments, after a thermal bake comprising 200° C. for 1000 hours, the resistance of at least 99.56 percent of the interconnects have changed by less than about 50 percent. Those of ordinary skill in the art are familiar with conventional quality assurance monitoring procedures to measure yield and reliability.

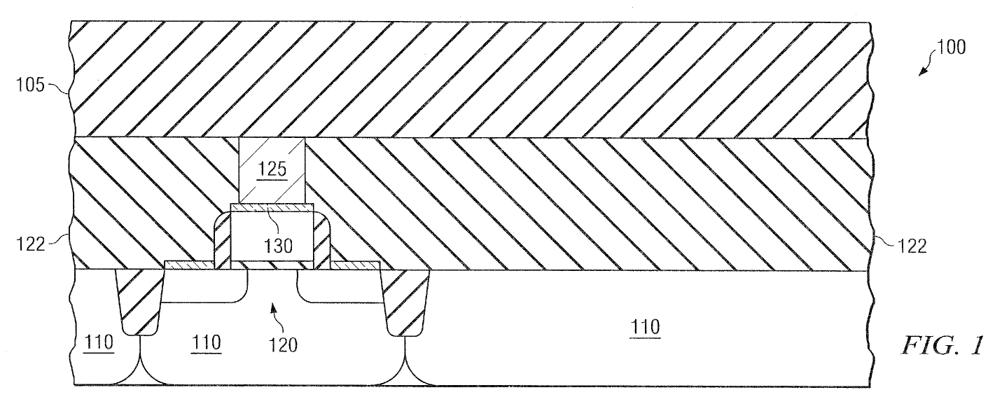

One embodiment of the invention is a method of manufacturing a semiconductor device. FIGS. 1-9 show cross-sectional views at selected steps in an example method of manufacturing a semiconductor device 100 of the invention. The device 100 can comprise a portion of an IC, an IC, or a plurality of ICs. In some embodiments, the semiconductor device 100 comprises one or a plurality of ICs that are intended to work together to form e.g., power amplifiers, Surface Acoustic Wave (SAW) filters, flash or static random access memory, inductors or MIM capacitors, or other digital logic or analog devices known to those skilled in the art.

FIG. 1 shows the device 100 after forming an insulating layer 105 over a semiconductive substrate 110. The substrate 110 can comprise any conventional substrate such as a wafer made of silicon, including silicon-on-oxide (SOI) substrates, silicon-germanium, or other materials well-known to those skilled in the art. The substrate 110 can include other conventional materials, such as oxide and metal layers, used in the manufacture of active or passive devices.

The insulating layer 105 can comprise any conventional dielectric material, such as silicon dioxide, silicon carbonitride, organo-silicate glass (OSG), fluorosilicate (FSG) tetraethyl orthosilicate (TEOS) or combinations thereof, including multi-layered combinations thereof. The insulating layer 105 can be formed using conventional techniques, such as Plasma Enhanced Chemical Vapor Deposition of silicon dioxide, or other dielectric materials, to a desired thickness (e.g., about 0.03 to 3 microns) under conditions known to those of ordinary skill in the art.

FIG. 1 also shows the device after forming electrical components 120 in or on the substrate 110 using conventional procedures known to those skilled in the art. Example electrical components 120 include pMOS and nMOS transistors, CMOS, BiCMOS devices, bipolar, or other conventional active or passive integrated circuit components, or combinations thereof. One or more insulating layers 122 can be located between the insulating layer 105 and substrate 110. The device 100 may further comprise metal contacts 125 (e.g., tungsten via contacts) that are configured to extend from electrode structures 130 of the components 120 (e.g., silicide electrodes) to one or more overlying copper interconnects 200.

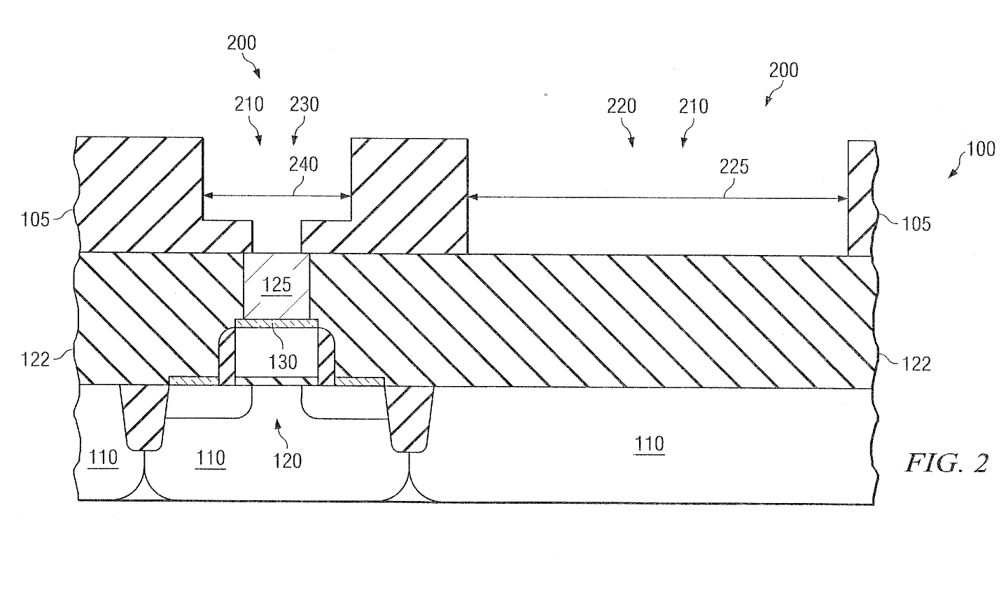

FIGS. 2-8 shows the device 100 at selected stages of forming one or more copper interconnects 200. The interconnects 200 are configured to couple the electrical components 120 together.

FIG. 2 shows the device 100 after etching one or more interconnect openings 210 in the insulating layer 105. The openings 210 can comprise vias, trenches or lines, including single or dual damascene integration schemes. The openings 210 can comprise wide trenches 220 (e.g., a width 225 of about 3 microns or greater, and in some cases, about 3 to 35 microns) or narrow trenches 230 (e.g., a width 240 of less than about 3 microns, and in some cases, about 0.1 to 0.5 microns). Openings of different widths are also within the scope of the invention. Conventional photolithography and etching processes may be used to form the openings 210.

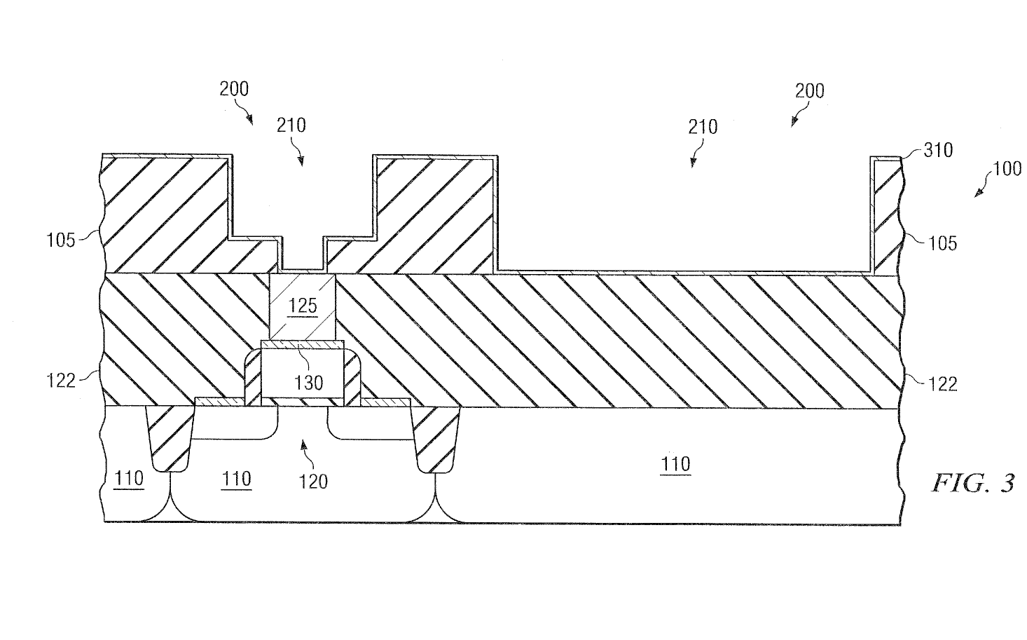

FIG. 3 shows the device 100 after forming a barrier layer 310 in the interconnect 200. The barrier layer 310 may be formed by any conventional process, such as atomic layer deposition (ALD), physical vapor deposition (PVD), chemical vapor deposition (CVD), electro-less deposition, or combinations thereof. As illustrated in FIG. 3, the barrier layer 310 conformally covers the insulating layer 105 and openings 210. The barrier layer 310 may comprise any conventional material used to provide a barrier against the diffusion of copper into the substrate 110 or components 120. Examples of barrier materials include metals or metal alloys such as tantalum, tantalum nitride or a combination thereof. Other example barrier materials include titanium, zirconium, ruthenium, iridium, iridium oxide, platinum, or combinations thereof.

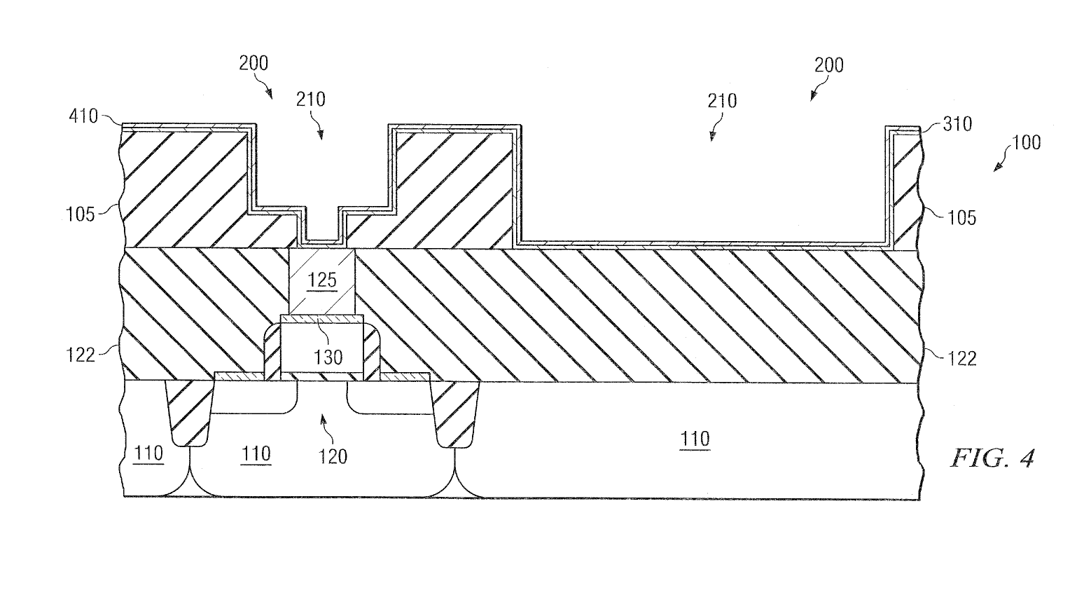

FIG. 4 shows the device 100 after forming a seed layer 410 in the interconnect 200. The seed layer 410 can be formed by any conventional process, such as PVD. A PVD of the seed layer 410 comprises sputtering, although other PVD methods, such as evaporation, may be used. As illustrated in FIG. 4, the deposited seed layer 410 conformally covers the insulating layer 105 and openings 210, and is on the barrier layer 310. In some embodiments, the seed layer 410 comprises copper, but in other embodiments, it may be pure copper. To mitigate attack by electrochemical plating chemistries, the seed layer 410 can comprise a copper alloy such as copper and one or more of Sn, Pd, C, Ca, Mg, Al, or Hf.

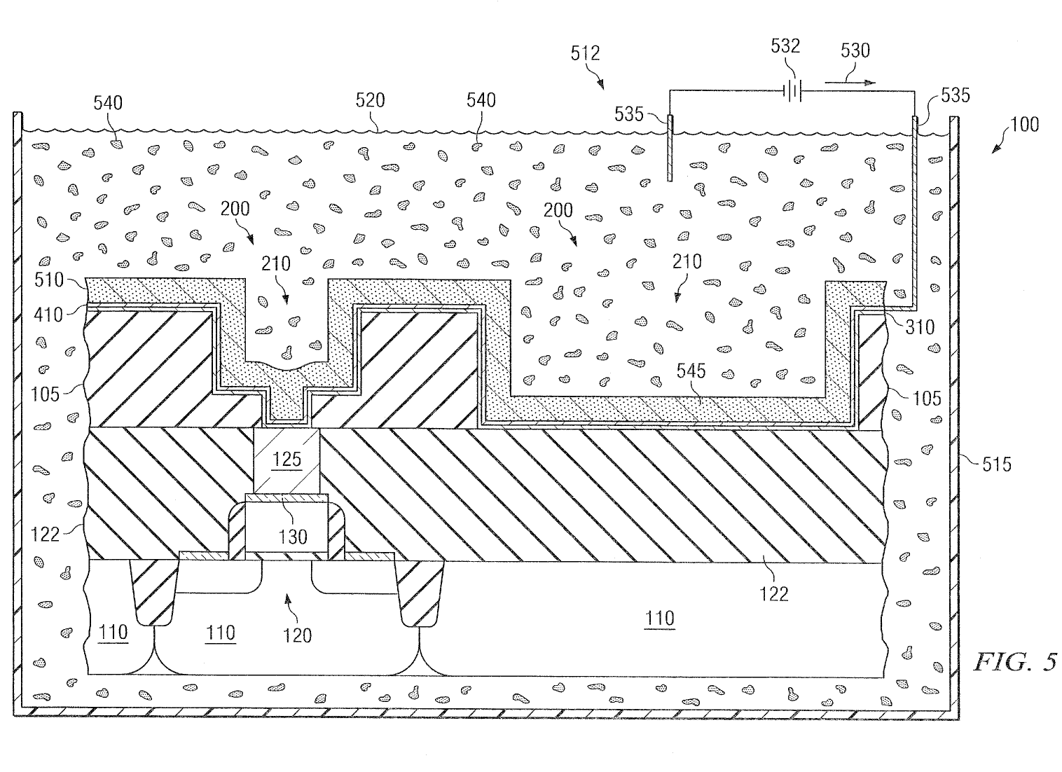

FIG. 5 shows the device 100 after filling the opening 210 with a first copper plating 510 during a first ECD step 512. As illustrated in FIG. 5, the substrate 110 is placed in a bath 515 containing electrolyte solution 520, and a first current 530 is applied to initiate the plating process, via a voltage source 532 and electrodes 535. The electrolyte solution 520 can contain conventional chemicals to facilitate the electrodeposition of copper. E.g., electrolyte solutions may comprise copper sulfate, sulfuric acid, and hydrochloric acid. Those skilled in the art are familiar with the concentrations and relative amounts of these and other such chemicals typically used in copper electroplating.

The electrolyte solution 520 also contains organic additives 540 to facilitate the growth of the copper plating 510 in the opening 210 without void formation in the opening 210. E.g., some embodiments of the organic additives 540 facilitate the formation of copper plating 510 from the bottom of the openings 210 upwards. Some examples of organic additives 540 comprise suppressors, accelerators or levelers. As known to those skilled in the art, these organic additives 540 can facilitate the deposition of copper with a tighter grain structure, suppress void formation in high-aspect-ratio openings, and enable planarization over topography.

The first current 530 is configured to initiate and maintain the plating of copper on the seed layer 410 for a period, and thereby produce high yields of low resistance interconnects. The first current may also cause incorporation of a first amount of organic additive by-products 545 in the first copper plating 510. As part of the present invention, it was discovered that the magnitude of first current 530 conducive to initiating and maintaining copper plating does not produce sufficient amounts of by-products 545 to facilitate the production of more reliable interconnects.

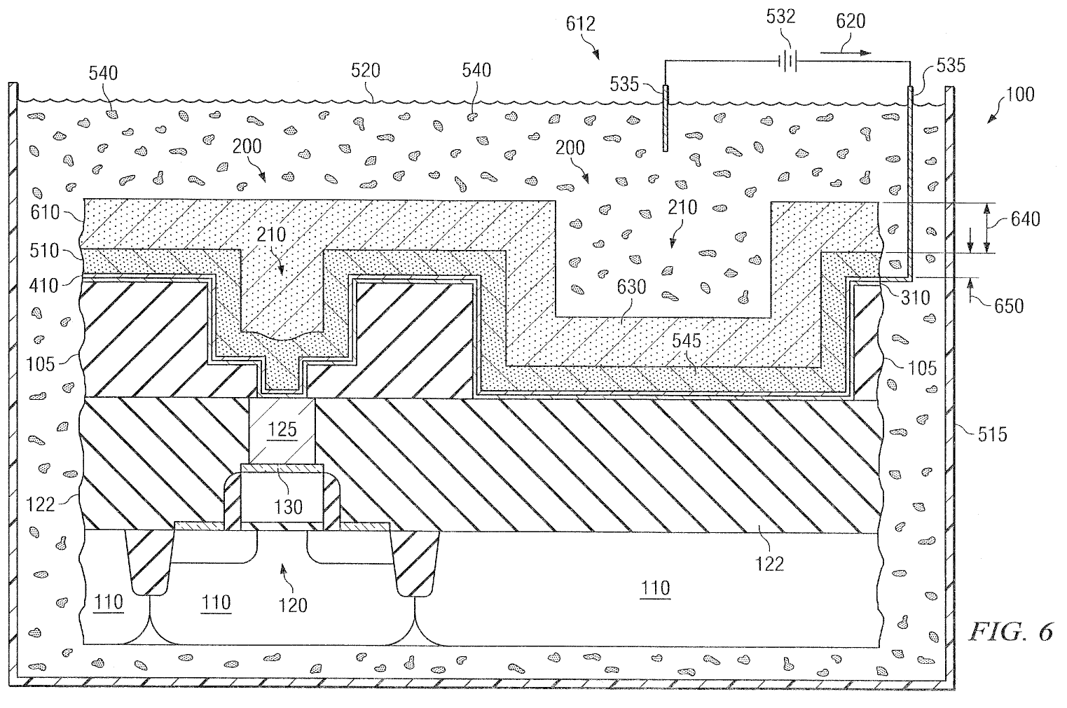

FIG. 6 shows the device 100 after filling the opening 210 with a second copper plating 610 during a second ECD step 612. In such embodiments, the substrate 110 is kept in the same electrolyte solution 520 as used in the first ECD step 512 (FIG. 5). However, a different electrolyte solution is used. During the second ECD step 612 a second current 620 is applied to continue the copper plating process. The first current 530 is greater than the second current 620.

The second current 620 is conducted in a way to incorporate higher amounts of organic additive by-products while maintaining the copper plating process. E.g., a second amount of organic additive by-products 630 produced in the second copper plating 610 is greater than the first amount of by-products 545 in the first copper plating 510 (FIG. 5). Consequently, for at least some interconnects 200 (e.g., wide trenches 220; FIG. 2), there is a higher concentration of organic additive by-products 630 in a central location of the interconnect 200 than in a peripheral location of the interconnect 200. That is, the central location has a higher average organic additive by-products 630 concentration than in the peripheral location. A higher amount of by-product 630 is thought to reduce the self-diffusivity (or stress migration) of the second plated copper 610 such that the interconnect 200 has greater reliability as compared to an interconnect formed without using the second ECD step 612.

In certain embodiments, a ratio of the first ECD current 530 to second ECD current 620 (FIGS. 5 and 6) is at least about 1.5:1. In other embodiments this ratio ranges from about 1.5:1 to 3:1. These ratios promote the increased incorporation of organic additive by-products 630 while maintaining the deposition of the second copper plating 610 at an acceptable rate (e.g., at least about 1 nm thickness of copper per second). E.g., for a 300 mm water diameter, the first ECD current density 530 ranges from about 5 to 11 mAmps/cm², and the second ECD current density 620 ranges from about 1.5 to 6 mAmps/cm².

It is advantageous for the openings 210 to be predominantly filled with the second copper plating 610 having the higher amount of by-product 630 therein. This is beneficial for interconnects 200 that are particularly susceptible to failure modes, such as stress migration (e.g., wide metal lines, greater than 3 microns, connected to isolated vias), because high concentrations of by-products 630 promote the formation of desirable copper grain structures in the opening 210. E.g., in some embodiments, a ratio of a thickness 640 of the second copper plating 610 to a thickness 650 of first copper plating 510 ranges from about 3:1 to 5:1. To achieve such thickness ratios, it is preferable for a ratio of Coulombs applied during the second ECD step versus the first ECD step to equal the desired thickness ratio (e.g., a Coulomb ratio ranging from about 3:1 to 5:1).

Consider an example embodiment where the first ECD step 512 comprises a first current 530 of about 7 Amps for about 7 seconds, corresponding to about 49 Coulombs, and resulting in a copper thickness 650 of about 27 nm. The second ECD step 612 comprises a second current 620 of about 3 Amps for about 70 seconds corresponds to about 210 Coulombs, resulting in a copper thickness 640 equal to about 114 nm. The Coulomb ratio (second ECD step to first ECD step) equals about 4:1, as does the thickness ratio.

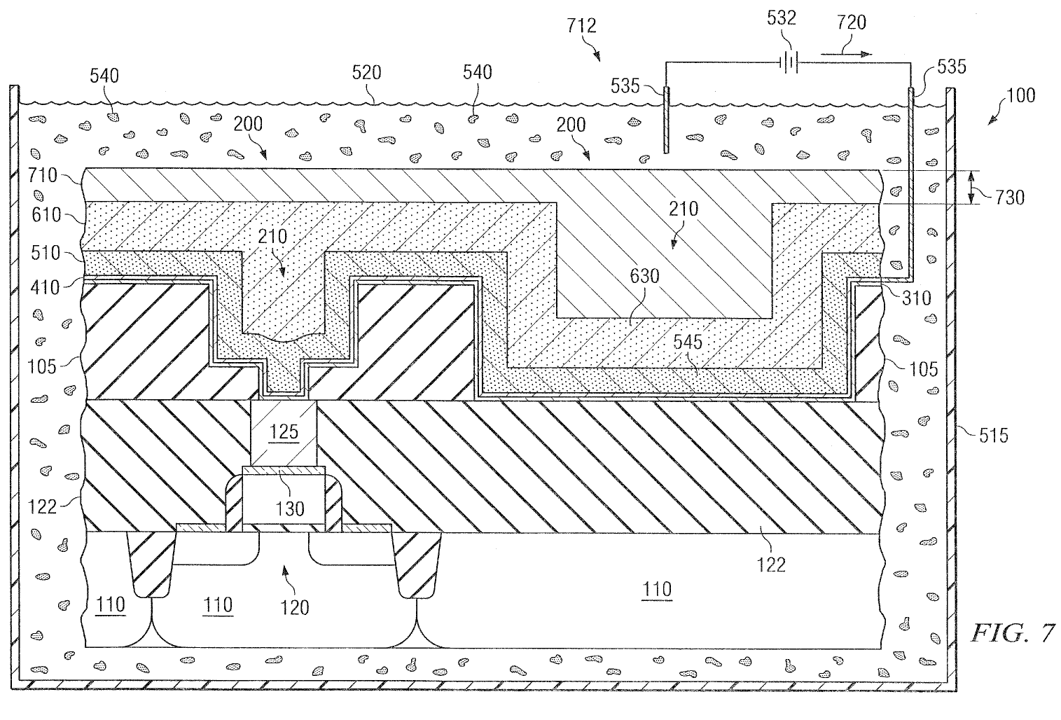

FIG. 7 shows the device 100 after depositing a third copper plating 710 during a third ECD step 712. During the third ECD step 712, a third current 720 is applied to continue the copper plating process. In some cases, the third copper plating 710 fills at least some of the openings 210, such as wide trenches 220 (FIG. 2). It is desirable to deposit an excessive amount of copper plating 710 (i.e., an overburden) during the third ECD step 712 so that sufficient copper remains within the interconnects after planarization (see e.g., patent application Ser. No. 10/901857, filed Jul. 28, 2004, incorporated by reference herein in its entirety).

In such embodiments, the substrate 110 is kept in the same electrolyte solution 520 as used to deposit the first and second copper plating 510, 610, although a different electrolyte solution could be used, if desired. The third current 720 is substantially greater than the first or second currents 530, 620. In certain embodiments, the third current 720 is at least about 2 times greater than the first current 530. In other embodiments a ratio of the third current 720 to the first current 530 ranges from about 2:1 to 10:1. It is desirable to rapidly deposit a thick layer of the third copper plating so as to minimize the total time required for copper plating (e.g., less than about 2 min in some cases).

A ratio of the thickness 730 of the third copper plating 710 to the thickness 650 of the first plating 510 (FIG. 6) may range from about 10:1 to 20:1. This thickness 730 can be achieved in a short period (e.g., less than 20 sec) by adjusting the third current 720 to a very high value. Continuing with the same example discussed above, after the first current 530 of 7 Amps and second current 620 of 3 Amps, the third current 720 of about 40 Amps is applied for about 19 seconds (about 760 Coulombs) resulting in a third plating 710 thickness 730 of about 413 nm. Thus, a Coulomb ratio of the (third ECD 712 to first ECD 512) equal to about 15:1, and a ratio of third thickness 730 to first thickness 650 equals about 15:1.

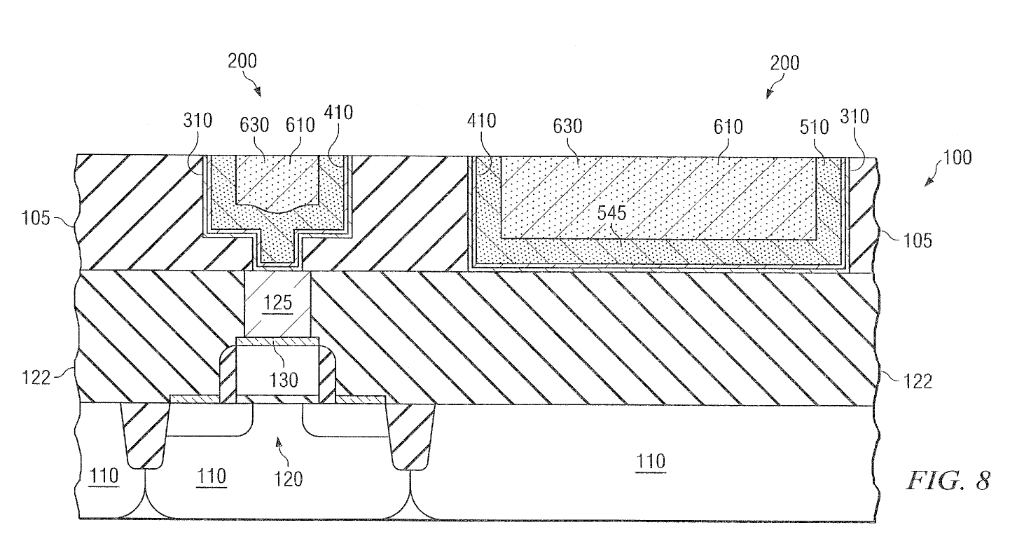

FIG. 8 shows the device 100 after planarizing the substrate 110 to remove portions of the barrier layer 310 (FIG. 7), seed layer 410 (FIG. 7) and copper plating 510, 610, 710 (FIG. 7) lying outside of the interconnects 200. Planarizing may be achieved by any conventional process, such as chemical mechanical polishing (CMP). To improve the grain structure of the electroplated copper, in some embodiments, a thermal anneal (e.g., about 150 to 300° C. for about 30 to 90 minutes) is applied before the CMP process.

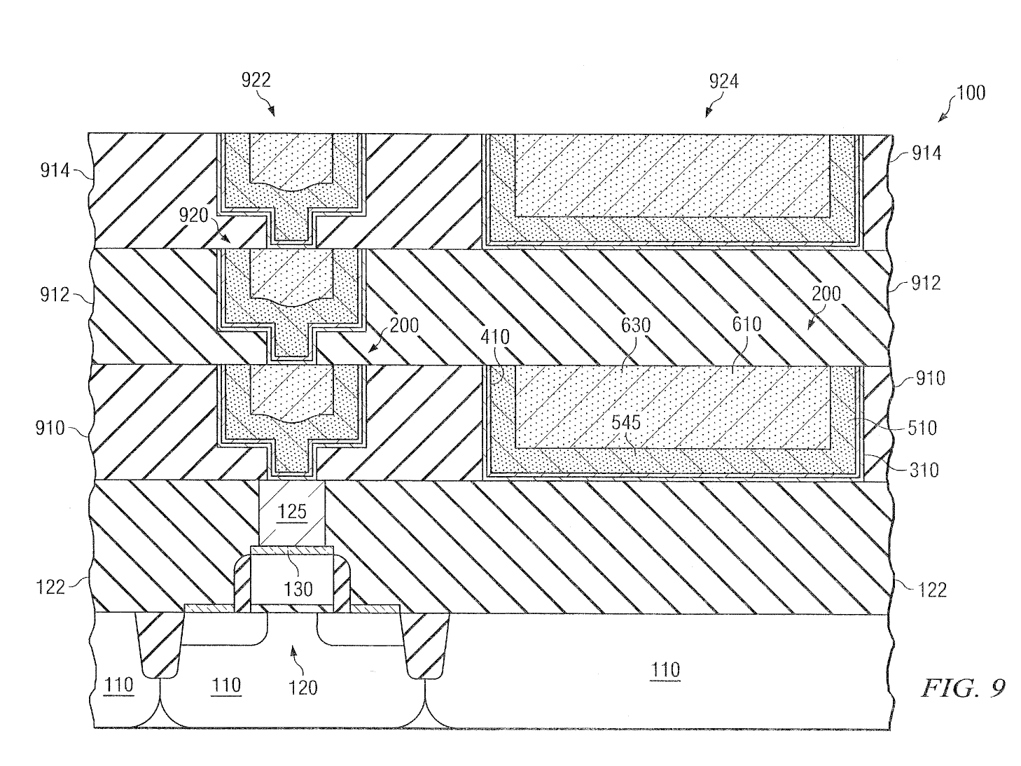

FIG. 9 shows the device 100 after repeating the method steps discussed above in the context of FIGS. 1-8 to form additional insulating layers 910, 912, 914 and copper interconnects 920, 922, 924 over the substrate 110 to complete the interconnection of the electrical components 120.

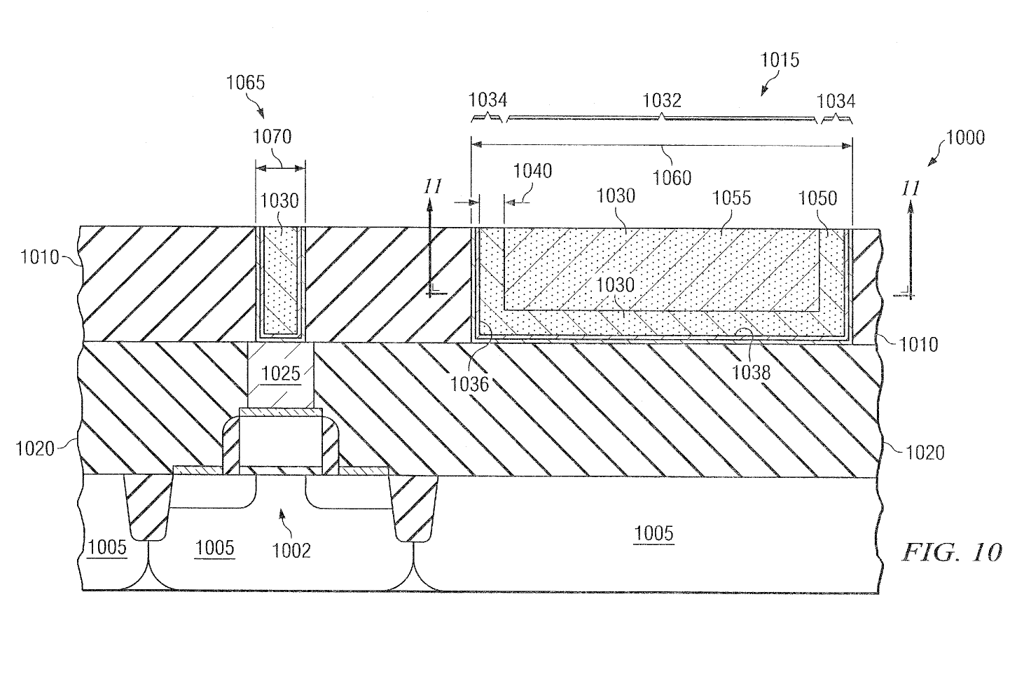

FIG. 10 also illustrates a cross-sectional view of another embodiment of the invention, an IC 1000. Any of the embodiments of the method described above can be used to manufacture the IC 1000. E.g., the IC 1000 can be the semiconductor device manufactured as described-above in the context of FIGS. 1-9.

The IC 1000 comprises electrical components 1002 (e.g., transistors) located in or on a substrate 1005, an insulating layer 1010 located over the electrical components 1002, and copper interconnects 1015 (e.g., vias, lines or trenches) located in the insulating layer 1010. The copper interconnects 1015 are configured to interconnect the electrical components 1002. There can also be additional insulating layers 1020 and vias 1025 (e.g., aluminum vias) that are configured to facilitate the connection between the electrical components 1002.

There is a higher concentration of organic additive by-products 1030 in a central location 1032 than in a peripheral location 1034 of at least one of the interconnects 1015. The term central location 1032 as used herein refers to an interior portion of the interconnect that does not contact the walls 1036 or bottom 1038 of the interconnect 1015. E.g., in some embodiments, the central location 1032 is separated from the walls 1036 or bottom 1038 by a distance 1040 of at least about 200 nm. This is in contrast to the peripheral location 1034, which contacts the walls 1036 and bottom 1038.

The organic additive by-products 1030 are generated during the electrochemical deposition of copper from an electrolyte solution of the first and said second ECD steps that contain organic additives as discussed above. Example organic additives include a sulfur-based organic molecule such as bis (sodiumsulfopropyl) disulfide (SPS) as an accelerator, a polyether such as polyethylene glycol (PEG) or polypropylene glycol (PPG) as a suppressor, and generally a polymer or nitrogen-based molecule such as Janus Green B (JGB) or thioruea, as a leveler. In some cases the organic additive by-products 1030 are generated from organic additives that comprise disulfides, thio-disulfides or poly-ethylene glycol.

The amount of organic additive by-products 1030 incorporated can be characterized by measuring concentrations of chloride, sulfur, or carbon in the interconnects 1015. Those skilled in the art understand how to measure concentrations of these elements at different locations in an interconnect, or in test copper layers designed to simulate an interconnect, using e.g., dynamic Secondary Ion Mass Spectroscopy (SIMS).

In certain embodiments, organic additive by-products 1030 are characterized by a concentration of chloride, sulfur, or carbon of at least about 100 ppm (by weight) in the central location 1032 of the interconnect 1015. In some cases the central location 1032 has from 10 to 800 ppm of chloride, 10 to 800 ppm of carbon and 10 to 800 ppm of sulfur. In other embodiments, a total concentration of chloride, sulfur, or carbon in the central location 1032 ranges from 10 to 1800 ppm. In still other embodiments, a ratio of chloride, sulfur, or carbon in the central location 1032 versus the peripheral location 1034 ranges from about 3:1 to 4:1.

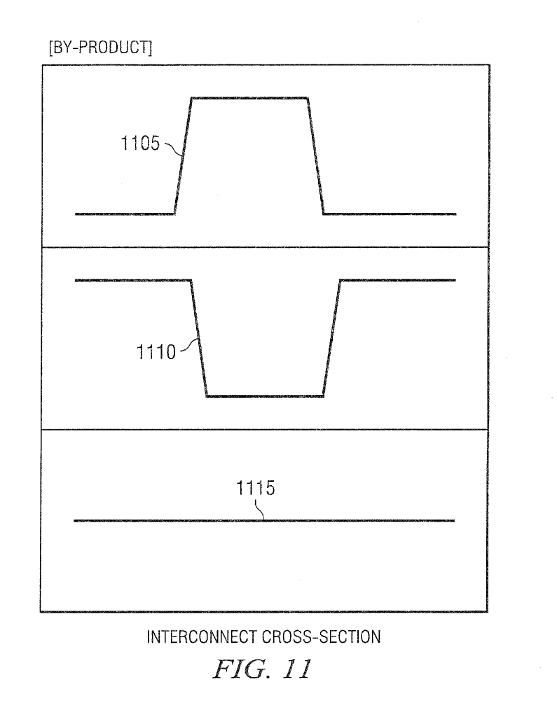

FIG. 11 illustrates various theoretical concentration profiles of incorporated organic additive by-products in an interconnect manufactured using three consecutive steps of differing currents in a manufacturing process analogous to that presented in FIGS. 1-9. The vertical axis corresponds to relative by-product concentration ([BY-PRODUCT]) while the horizontal axis corresponds to different lateral positions in the interconnect's cross-section along view line 11-11 in FIG. 10.

A high-low profile 1105 corresponds to the profile obtained for the interconnect 1015 (FIG. 10) when using current waveform that comprises a current of the first ECD step that greater than a current of the second ECD step. This is in contrast to a low-high profile 1110, where the current waveform comprises a first ECD step having a current that is less than a current of a second ECD step, or a flat profile 1115 where the current waveform comprises a substantially constant current.

Those skilled in the art understand that the relative magnitude and exact shape of the profiles 1105, 1110, 1115, depend on numerous fabrication-specific factors, including the duration and magnitude of the applied currents, the types and amounts of organic additives used, and whether the profile is measured before or after the interconnect is subjected to a thermal anneal. E.g., in some cases the high-low by-product concentration profile 1105 depicted in FIG. 11 may become more flattened after exposing the IC to a thermal anneal, such as discussed in the context of FIG. 8.

Returning to FIG. 10, to have the above-described by-product 1030 concentration profile (e.g., the high-low profile 1105 of FIG. 11), the interconnect 1015 should be sufficiently wide to permit the deposition of both first copper plating 1050 and second copper plating 1055 during first and second ECD steps, respectively, such as discussed above in the context of FIGS. 5-6.

In some embodiments, the interconnect 1015 has a width 1060 of at least about 3 microns, and in other cases ranges from 3 to 35 microns. A narrower interconnect 1065 (e.g., having a width 1070 of about 1 micron or less in some cases, and in other cases, from about 0.1 to 0.5 microns) does not have higher by-product 1030 concentrations in its central location 1032 because the interconnect is substantially filled with only the first copper plating 1050. One skilled in the art understand that the width 1060 that is conducive to forming high central by-product concentrations depends on numerous fabrication-specific factors, including the thicknesses of the barrier layer, the seed layer, and the first and second copper plating, as well as the types and amounts of organic additives used.

Interconnects 1015 having the higher central concentration of by-products 1032 are more reliable than interconnects of similar dimension and composition but without the higher by-product concentration.

Consider, as an example, copper interconnects 1015 constructed to have a width 1060 of about 3 or about 4.4 microns and having copper plating that comprises a high-low profile 1105 of by-products 1030 (FIG. 11). In one embodiment, a first current of about 7 Amps was applied for about 7 seconds, and then a second current of about 3 Amps was applied for about 70 seconds. This was followed by a third current of about 40.5 Amps for 18.75 seconds. For comparison, interconnects were formed using a flat profile 1115 (FIG. 11) comprising a current of 7 Amps for 37 seconds, followed by a second current of about 40.5 Amps for 18.75 seconds. Copper plating was performed in an electrolyte solution comprising: 20-50 g/L Cu²⁺, 1-20 g/L, H₂SO₄, 35-50 g/L Cl⁻¹, and organic additives comprising a suppressor of 1-2 ml/L, an accelerator of 5-10 ml/L and a leveler of 1-2 ml/L.

The resistance of the interconnects 1015 constructed with the high-low profile 1105 was assessed by measuring the resistance of vias electrically coupled to the interconnects 1015. A via resistance of about 10 ohms or less was obtained for about 99.98% of the vias tested. The resistance of 99.87 percent the vias electrically connected to metal lines of about 4.4 microns changed by less than about 50 percent after a thermal bake comprising 200° C. for about 1000 hours. In comparison, 1.6 percent of vias electrically connected to metal lines of about 4.4 microns constructed with the flat profile 1115 had an increase in resistance in excess of 50 percent after the same thermal bake.

Although the invention has been described in detail, those skilled in the art should understand that they could make various changes, substitutions and alterations herein without departing from the scope of the invention in its broadest form.

1. A method of manufacturing a semiconductor device, comprising:
forming an insulating layer over a semiconductive substrate; and
forming a copper interconnect, including:
etching an interconnect opening in said insulating layer; and
filling said opening with copper plating, including:
using a first electrochemical deposition, and
using a second electrochemical deposition;
wherein an electrolyte solution of said first and said second electrochemical deposition contains organic additives, and
a current of said first electrochemical deposition is greater than a current of said second electrochemical deposition.

2. The method of claim 1, wherein a ratio of said first electrochemical deposition current to said second electrochemical deposition current is at least about 1.5:1.

3. The method of claim 2, wherein said ratio ranges from about 1.5:1 to 3:1.

4. The method of claim 1, wherein said first electrochemical deposition current density ranges from about 5 to 11 mAmps/cm² and said second electrochemical deposition current density ranges from about 1.5 to 6 mAmps/cm².

5. The method of claim 1, wherein a ratio of Coulombs during said second electrochemical deposition to said first electrochemical deposition ranges from about 3:1 to 5:1.

6. The method of claim 1, wherein a ratio of thickness of copper deposited during said second electrochemical deposition to said first electrochemical deposition ranges from about 3:1 to 5:1.

7. The method of claim 1, wherein there is a higher concentration of organic additive by-products in a central location than in a peripheral location of at least one of said interconnects.

8. The method of claim 1, wherein said filling further includes a third electrochemical deposition, wherein said third electrochemical deposition is greater than said first electrochemical deposition current.

9. The method of claim 8, wherein a ratio of said third electrochemical deposition current to said first electrochemical deposition current ranges from about 2:1 to 10:1.

10. A method of manufacturing an integrated circuit, comprising:
forming electrical components in or on a substrate;
depositing an insulating layer on said substrate; and
forming copper interconnects configured to couple said electrical components together, including:
etching an interconnect opening in said insulating layer;
depositing a barrier layer and a seed layer in said opening; and
filling said opening with copper, including:
a first electrochemical deposition, and
a second electrochemical deposition;
wherein an electrolyte solution of said first and said second electrochemical deposition contains organic additives comprising at least one of: suppressors, accelerators or levelers, and a current of said first electrochemical deposition is greater than a current of said second electrochemical deposition.

11. An integrated circuit (IC), comprising:
electrical components located in or on a substrate;
an insulating layer located over said electrical components; and
copper interconnects in said insulating layer configured to interconnect said electrical components,
wherein there is a higher concentration of organic additive by-products in a central location than in a peripheral location of at least one of said interconnects.

12. The IC of claim 11, wherein said organic additive by-products in said interconnects are characterized by a concentration of chloride, sulfur, or carbon of at least about 300 ppm in said central location.

13. The IC of claim 11, wherein said organic additive by-products are generated from the electrochemical deposition of copper from an electrolyte solution of said first and said second electrochemical deposition contains organic additives comprising at least one of: suppressors, accelerators or levelers.

14. The IC of claim 13, wherein said organic additive by-products are generated from said organic additives.

15. The IC of claim 13, wherein said organic additive by-products are generated from said organic additives that comprise disulfides, thio-disulfides or poly-ethylene glycol.

16. The IC of claim 11, wherein said at least one interconnect has a width of at least about 3 microns.

17. The IC of claim 13, wherein said at least one interconnect has a width that ranges from about 3 to 35 microns.

18. The IC of claim 13, wherein said central location is separated from walls or a bottom of said at least one interconnect by a distance of at least about 200 nm.

19. The IC of claim 11, wherein a resistance vias electrically coupled to said at least one interconnect changes by less than 20 percent after a thermal bake comprising 200° C. for about 168 hours.

20. The IC of claim 19, wherein said resistance equals about 10 ohms or less.
